(19) United States
(12) Patent Application Publication
(10) Pub. No.: US 2016/0195586 A1
(43) Pub. Date: Jul. 7, 2016

(54) ENERGY MANAGEMENT IN A BATTERY

(71) Applicant: COMMISSARIAT A L'ENERGIE ATOMIQUE ET AUX ENERGIES ALTERNATIVES, Paris (FR)

(72) Inventors: Nicolas Martin, Peyrieu (FR); Maxime Montaru, Joursac (FR)

(73) Assignee: Commissariat à I'Énergie Atomique et aux Énergies Alternatives, Paris (FR)

(21) Appl. No.: 14/909,446

(22) PCT Filed: Aug. 1, 2014
(86) PCT No.: PCT/FR2014/052015

§ 371 Date: Feb. 1, 2016

(30) Foreign Application Priority Data
Aug. 2, 2013 (FR) 1357717

(51) Int. Cl. G01R 31/36

(52) U.S. Cl. CPC G01R 31/3651; G01R 31/3679; G01R 31/3634

(57) ABSTRACT

A method for calibrating an algorithm for estimating a state variable of a battery comprising the following steps: measuring at least one physical quantity of the battery making it possible to detect a first characteristic value of the state variable at a first time; defining a period between the first time and a second time; measuring at least one physical quantity of the battery making it possible to detect a second real characteristic value of the state variable at a second time; comparing, at the end of said period, an estimated value of said variable provided by the algorithm with said second characteristic value; and adapting at least one parameter of the algorithm on the basis of the comparison. The invention also concerns a circuit for determining a state variable of a battery, suitable for implementing said method.

The present patent application claims the priority benefit of French patent application FR 13/57717 which is herein incorporated by reference.

### BACKGROUND

The present description generally relates to the management of a battery and, more particularly, to the sampling of an algorithm for estimating a state of charge or of aging of a battery.

### DISCUSSION OF THE RELATED ART

Most batteries, be they high-, medium-, or low-power batteries, are associated with energy management electronic circuits, and particularly circuits for managing their charge. Such circuits generally process information relative to the state of charge of the battery. This information is not easily directly measurable. State-of-charge (generally called SOC) estimation algorithms which provide an estimate of the SOC from various measurements are thus used. Such algorithms use a set of parameters and are generally calibrated based on measurements carried out on battery prototypes.

Algorithms already present on batteries may if need be be calibrated during maintenance operations. However, such calibrations are not capable of processing possible dispersions between batteries of a same type. Further, usual methods are incompatible with a real-time calibration of the state-of-charge calculation algorithm.

Document EP-A-1265335 describes a method and a device for controlling the residual charge capacity of a secondary battery and provides successively obtaining the voltage, the current, and the temperature of the battery, calculating the SOC by integration of the current, calculating an average value of the battery voltage over a predetermined period, calculating an average value of the SOC over a predetermined period, comparing the average value of the voltage with a reference value based on the average value of the SOC and temperature, and parameterizing the faradaic efficiency of the battery. This amounts to adjusting the faradaic efficiency according to the interval between the average value of the voltage and a reference value. However, the obtaining of the reference value, which is a function of the SOC, of the current, and of temperature, is complex.

### SUMMARY

An embodiment of the present description aims at a method of estimating a state variable of a battery which overcomes all or part of the disadvantages of usual methods. More particularly, an embodiment aims at adjusting the faradaic efficiency in a simpler way than usual solutions.

An embodiment of the present description aims at a method of calibrating an algorithm for estimating a state variable of a battery.

An embodiment of the present description aims at a method more particularly capable of estimating the state of charge of a battery.

An embodiment of the present description aims at a method which may be implemented on site.

An embodiment of the present description aims at a method compatible with a periodic recalibration of batteries in operation.

Thus, an embodiment aims at a method of calibrating an algorithm for estimating a state variable of a battery, comprising the steps of:

measuring at least one physical variable of the battery enabling to detect a first real characteristic value of the state variable at a first time;

defining a period between the first time and a second time;

measuring at least one physical quantity of the battery enabling to detect a second real characteristic value of the state variable at a second time;

comparing, at the end of said period, an estimated value of said variable provided by the algorithm with said second characteristic value; and

adapting at least one parameter of the algorithm according to the comparison.

According to an embodiment, the parameter is the faradaic efficiency ηᵢ of the battery (1), calculated for said period by applying the following relation:

ηᵢ*Ah_{ch}=ηᵢ₋₁*Ah_{ch}+ΔCnom,

where Ah_{ch} represents the number of cumulated amperes-hours of the battery in charge phase during the period, ηᵢ₋₁ represents the faradaic efficiency of the previous period, and ΔCnom corresponds to the interval between the value of the state variable (SOC) at the end of a period and an estimated value.

According to an embodiment, said first and second characteristic values are equal.

According to an embodiment, said parameter is adapted so that the application, at the beginning of said period, of the adapted parameter value would have resulted, at the end of the period, in an identity during the comparison of said state variable values, the adapted parameter being used for a new period between two times characteristic of said state variable.

According to an embodiment, estimated values of said variable, provided by the algorithm during said period, are stored, the stored values being used to adapt at least one parameter of the algorithm.

According to an embodiment, the variation, during said period, of one or a plurality of physical quantities influencing said variable, is stored, the values of the stored physical quantities being used to adapt at least one parameter of the algorithm.

According to an embodiment, said quantity or quantities are selected from among the voltage across the battery, the charge or discharge current, the number of amperes-hours, the temperature, and the acoustic emissions of the battery.

According to an embodiment, the state variable is the battery state of charge.

According to an embodiment, the state variable is the battery state of aging.

An embodiment also aims at a method for estimating a state variable of a battery comprising calibration phases such as described hereabove.

An embodiment also aims at a circuit for determining a state variable of a battery, capable of implementing the estimation or calibration method.

### BRIEF DESCRIPTION OF THE DRAWINGS

The foregoing and other features and advantages will be discussed in detail in the following non-limiting description of specific embodiments in connection with the accompanying drawings, among which:

FIG. 1 is a very simplified representation of a battery management system of the type to which the embodiments which will be described apply;

FIG. 2 is a timing diagram illustrating an embodiment of a method of calibrating a circuit for estimating the state of charge of a battery;

FIG. 3 is a block diagram illustrating another embodiment of the method of calibrating a circuit for estimating the state of charge of a battery; and

FIG. 4 is a timing diagram illustrating the operation of the embodiment of FIG. 3.

### DETAILED DESCRIPTION

The same elements have been designated with the same reference numerals in the different drawings. Further, only those steps and elements which are useful to the understanding of the embodiments which will be described have been shown and will be detailed. In particular, the processing of the information relative to the state of charge by battery management systems has not been detailed, the described embodiments being compatible with usual mechanisms for processing such charge estimates.

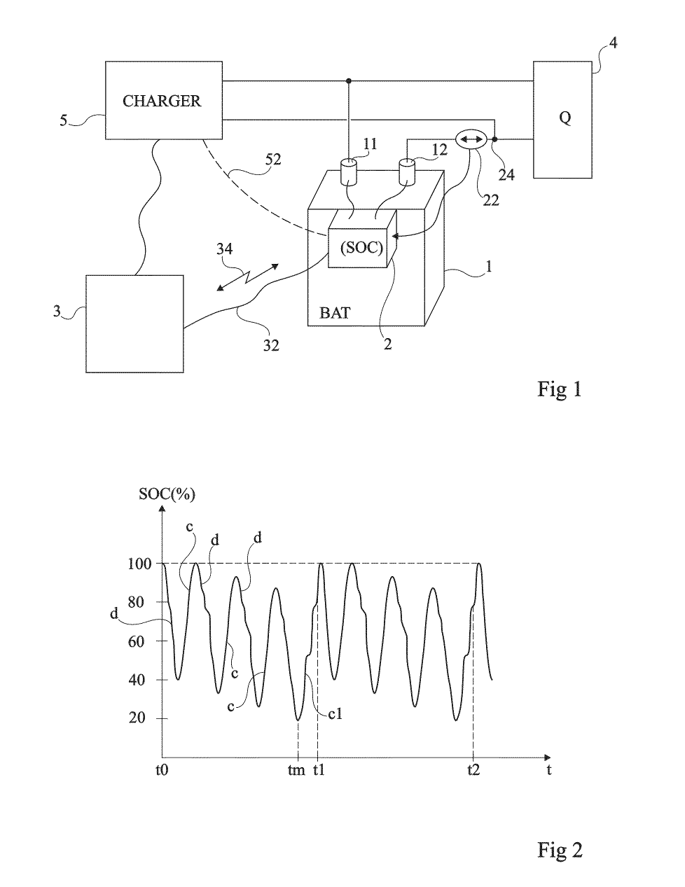

FIG. 1 very schematically shows a battery 1 (BAT) for powering a device 4 (Q) associated with a circuit 2 for calculating its state of charge. The monitoring of the battery state of charge is used, among others, to control a battery charger 5 (CHARGER). Circuit 2 may contain the entire battery management system or a portion of this system may be decentralized in a distant device 3, in particular to manage sets of batteries. Circuit 2 communicates with distant device 3 in wired (connection 32) or wireless (connection 34) fashion, and possibly directly with the charger (connection in dotted lines 52). Decentralized system 3 means, at the same time, circuits shared by a plurality of batteries of a same set (battery pack) and more distant systems, for example, control rooms managing a battery fleet. The energy management may take various forms such as, for example, switching charge 4 to an economical operating mode when the discharge reaches a threshold, stopping the discharge when the charge level reaches a critical threshold, etc.

Electronic circuit 2, for example, of microprocessor type, attached to the battery is generally connected to the two battery electrodes 11 and 12 to be able to measure the voltage across the battery. Further, circuit 2 receives information originating from a current sensor 22, for example, between one of electrodes 11 and 12 and a node 24 of connection to load 4 and to charger 5. Circuit 2 generally draws the energy necessary to its operation from the actual battery 1. In practice, load 4 and charger 5 are most often connected to circuit 2, which integrates current sensor 22, only circuit 2 being connected to the battery electrodes.

Most of circuits 2 which monitor the state of charge of the battery use a SOC calculation algorithm which takes into account the current transiting through the battery, the faradaic efficiency, and the nominal capacity of the battery. Certain algorithms also take temperature into account. SOC calculation algorithms use current measurements and calculate amounts of electricity during the charge and the discharge in amperes-hours. The calculation of the SOC at a given time depends on the SOC at the previous time. The state of charge is generally expressed in percent of the total battery charge.

In practice, the battery management comprises preventing it from reaching critical values, for the application or for the operation of the actual battery. For example, for the application, that is, the powered load, it may be desired to avoid for the battery state of charge to no longer be sufficient to properly stop the application (for example, save data, set the circuits to stand-by, etc.). According to another example, in the case where the battery itself risks being damaged if it discharges too much, a minimum state-of-charge limit is set (for example, 20%).

However, if the state-of-charge estimation algorithm drifts and no longer indicates a reliable value, this adversely affects the battery management. For example, if the algorithm provides an undervalued SOC value, the battery management system will stop the application or restrict its operation even though this is not justified. Conversely, an overvaluing will cause the stopping of the battery charge while it is not fully charged.

A currently-used algorithm calculates the SOC according to the following relation:

$$SOC = \frac{η * \int I d t}{{C}_{nom}} + SOCi , \qquad ( 1 )$$

where η represents the faradaic efficiency of the battery, I represents the current in algebraic value transiting through the battery, and Cnom represents the nominal capacity of the battery. The integration period generally corresponds to the time elapsed since a known state of charge SOCi.

Parameter η generally takes a different value according to whether the battery is charging or discharging. For example, this coefficient may be 1 in a discharge cycle and 0.97 in a charge cycle.

This is an example only and other SOC algorithms use other relations. However, these algorithms have in common to take into account at least one parameter, here, η, which is different according to whether the cycle is a charge cycle or a discharge cycle. This parameter is sometimes adjusted during maintenance operations to adjust the algorithm.

It is provided to vary this parameter, or more generally an adjustable parameter of the algorithm enabling to correct the value of the SOC provided by the algorithm, automatically on site. To achieve this, it is provided to exploit known, that is, measurable states of charge, to be able to compare these values with the values provided by the algorithm and accordingly modify parameter η.

It could have been devised to perform a measurement, for example, to adjust the value provided by the algorithm to 100% at the end of each charge cycle. This is however not realistic since the charge cycles may be interrupted before reaching a full charge. For example, in the case of a battery recharged by a solar charger, the charge during the day may result being incomplete.

It is thus provided to only perform this adjustment or recalibration on characteristic points or values. Such characteristic values do not necessarily correspond to a full charge (100%) or to a total discharge (0%). Preferably, the adjustment is performed periodically by determining a time window representing a number of charge/discharge cycles. This window represents a minimum time period between two times of calibration of the algorithm. The recalibration is then performed on a characteristic point, preferably the first characteristic point which follows the end of this time period.

A characteristic point or value corresponds to a state of charge for which the real value of the state of charge can be obtained by measurement of one or a plurality of physical quantities of the battery. For example, states 0% and 100% are generally known, that is, for the considered battery, the values taken by measurable quantities (for example, the pair of values of the voltage across the battery and of the current that it outputs) when the battery is in the characteristic states are known. They generally correspond to cases where the battery is in full charge or when it is fully discharged. Between these two values, the value of the SOC is generally estimated by means of the calculation algorithm, which generally takes into account the current which flows through the battery.

At a characteristic point, the real value of the SOC originating from the measurement of physical quantities can be compared with the value estimated by the SOC calculation algorithm.

It is thus provided to adjust a parameter of the SOC calculation algorithm when the battery reaches a value which corresponds to a known state (0.100% for example). Such an adjustment aims at modifying the SOC calculation so that the estimated SOC value corresponds to the real value at this time, to avoid for a drift to last.

Conversely to the solution described in document EP-A-1265335, the average SOC or voltage values are not processed, but series of values are analyzed. Further, values corresponding to characteristic points where the SOC value can be known, for example, states 0% or 100% (or other known intermediate states) are processed.

FIG. 2 illustrates an example of variation of a battery SOC. This drawing illustrates, from a time t0, different cycles of battery discharge d and charge c. A drift of the SOC estimation algorithm which results in a progressive undervaluation of the SOC value with respect to its real value is assumed. The extent of the drift has been exaggerated for illustration purposes. As a result, at a time tm, the algorithm provides a value, for example, in the order of 20%, while in reality the state of charge is in the order of 40%.

In a simplified example, it is considered that when the algorithm provides a SOC value reaching a limiting value (here, arbitrarily 20%) at the end of a discharge cycle, a calibration is started at the end of the full charge cycle which follows a calibration. In the shown example, at the next charge cycle c1, the SOC value is readjusted at time t1 when the charge reaches the full charge (detected by measurement and not by estimation) so that it corresponds to 100% (real value).

To determine that charge cycle c1 is effectively complete, the real SOC values are processed. In practice, the measured voltage and current values are compared with known values stored in circuit 2 as corresponding to a full charge.

The recalibration enables, at time t1, to adjust the value provided by the algorithm on a real value.

However, assuming that the charge and discharge cycles are, after time t1, identical to those present after time t0, the phenomenon is repeated, that is, the error provided by the SOC starts increasing again. Accordingly, at the next characteristic time t2, that is, the time when a new calibration is performed, the same error has to be made up for.

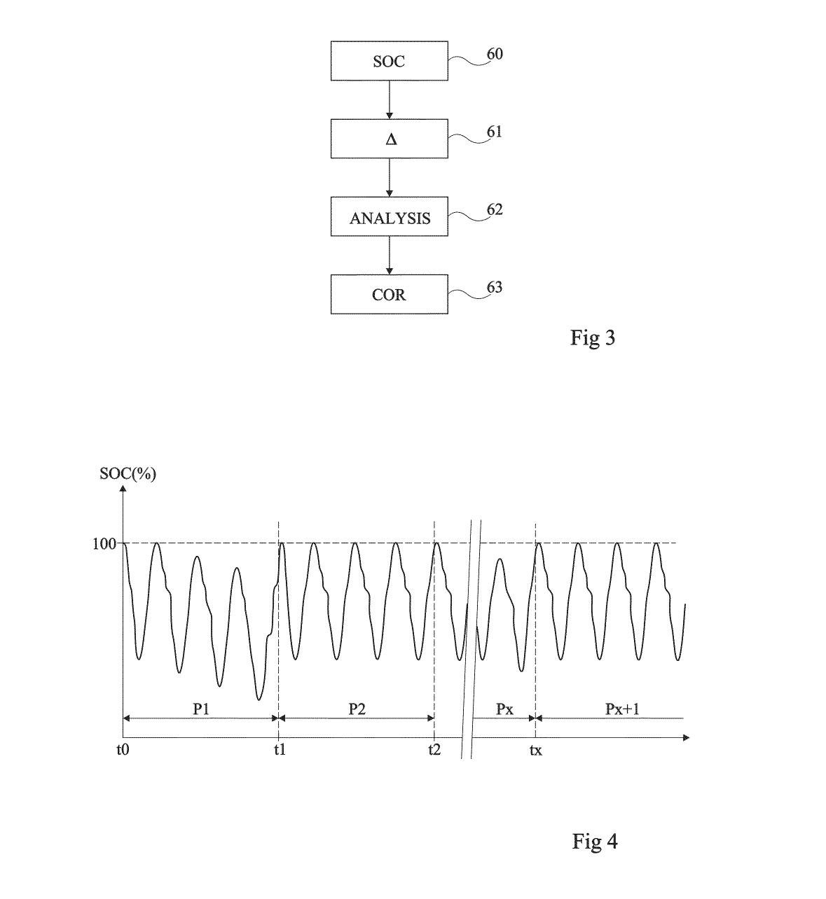

FIG. 3 is a simplified block diagram illustrating steps of implementation of the improved calibration method.

This method is based on the definition of a characteristic battery cycling period, that is, a period between two successive characteristic points.

FIG. 4 is a timing diagram to be compared with that of FIG. 2, and illustrates the implementation of the method of FIG. 3. FIG. 4 shows a plurality of periods Pi. These periods are arbitrarily identified as P1, P2, Px, and Px+1 between respective characteristic times t0 and t1, t1 and t2, tx−1 (not shown in the drawings) and tx, and tx and tx+1 (not shown in the drawing).

At each end of a period Pi, the interval Δ (block 61. FIG. 3) between the real characteristic end-of-period SOC value and the estimated value indicated by the SOC gauge (by application of the algorithm) is measured. This interval can be deduced from values of measured physical quantities, such that voltage U and current I in the battery. For example, a real SOC value will be obtained as soon as a triplet of voltage, current, and temperature measurements, which correspond to a given SOC, is obtained.

Correction COR (block 63) which should have been applied to the algorithm from time ti−1 to obtain the right SOC value at time ti can then be deduced.

Preferably, the correction takes into account an analysis (block 62, ANALYSIS) of the variation of the SOC value between two characteristic points according to the variation of quantities such as the voltage across the battery, the charge or discharge current, the number of amperes-hours, temperature.

Thus, in case of a similar drift, more specifically with no additional drift, during the next period Pi+1, a correct value is obtained at the end of this period (time ti+1).

Taking the example of a coefficient r, this amounts, noting Ah_{ch} the number of amperes-hours cumulated in the battery in charge phase between times tᵢ₋₁ and tᵢ, and ηᵢ the value of the coefficient for period Pi, to calculating coefficient ηᵢ by applying the following relation:

ηᵢ*Ah_{ch}=ηᵢ₋₁*Ah_{ch}+□Cnom, (2)

where □Cnom corresponds to the interval between the real end-of period SOC value and the estimated value indicated by the SOC gauge.

Selecting the characteristic times so that they correspond to a same characteristic value is a preferred embodiment, since it is particularly simple. However, according to an alternative embodiment, the characteristic values at the two successive characteristic times used by the algorithm calibration method are not identical. For example, the first characteristic value is a battery charge percentage and the second value is a different percentage. However, an estimated value is compared with a real value for each characteristic time.

According to an advantageous embodiment, during each period Pi (block 60, SOC), the variation of the estimated SOC value provided by the algorithm is recorded. Such a recording for example comprises storing successive values. The number of values conditions the accuracy which will be obtained afterwards. In practice, at least the minimum and maximum values are stored.

It is further desirable to also record the variation of physical quantities, such as current and voltage, or physical quantities linked to an environmental value, such as temperature.

Such recordings are more particularly advantageous in the case where the estimation algorithm is a function of the values of these physical quantities. An optimization algorithm, using the stored data, can then be used to define the best adapted parameters of the estimation algorithm.

The left-hand portion of FIG. 4 illustrates the case of a drift during period P1 which is similar to the drift present between times t0 and t1 of FIG. 2. As compared with FIG. 2, in the next period P2 where similar operating conditions are assumed, the estimated SOC value is corrected and is thus correct.

The right-hand portion of FIG. 4 illustrates the case of a new drift during period Px. The error linked to this new drift is estimated at time tx and the coefficient is adapted at time tx to compensate for this drift during the next period Px+1.

The fact of analyzing the variation of the SOC during a characteristic period enables to improve the correction of the parameters of the algorithm so that the drift which has appeared during a period is no longer present at the next period.

The selection of the parameter(s) to be taken into account depends on the implemented SOC algorithm. The selection of the environmental quantity or quantities to be taken into account in the analysis phase depends on the available quantities (easily measurable). Temperature and possibly a measurement of the acoustic emissions of the battery are currently used.

The described solution is particularly adapted to batteries which use generic SOC algorithms, which is the most current case since such algorithms are tried and tested. In such a case, there is a dispersion of the performances of the successive batteries manufactured from a same production line although they have the same SOC algorithm. It is thus advantageous to be able to adjust the parameters of this algorithm in operation.

This solution is also particularly adapted to batteries which are often used in the same way. Indeed, the correction is all the more accurate as the battery charge and discharge requirements are frequent and identical.

A similar technique may be implemented to adjust a parameter of a battery which is not its state of charge but, for example, its state of health (SOH). The characteristic times are then defined as the times when either the capacity of a battery or the state of its internal resistance can be measured. SOH algorithms implement parameters similar to SOC parameters.

Various embodiments have been described. Various alterations and modifications will occur to those skilled in the art. In particular, the selection of the parameters of the SOC algorithm to be adapted according to the cycling periods depends on the SOC algorithm used. Further, although an example where the characteristic point corresponds to a 100% charge, any characteristic point available for the considered system may be used, be it at the end of the charge or at the end of the discharge, or at an intermediate charge level. For example, in certain systems, a mid-charge state of the battery can be measured and a characteristic point at 50% can then be estimated. Finally, the practical implementation of the described embodiments is within the abilities of those skilled in the art based on the functional indications given hereabove and by using usual computer tools.

1. A method of calibrating an algorithm for estimating a state variable of a battery, comprising the steps of:
measuring at least one physical quantity of the battery enabling to detect a first characteristic value of the state variable at a first time;
defining a period between the first time and a second time;
measuring at least one physical quantity of the battery enabling to detect a second characteristic value of the state variable at the second time;
comparing, at the end of said period, an estimated value of said variable provided by the algorithm with said second characteristic value; and
adapting at least one parameter of the algorithm according to the comparison.

2. The method of claim 1, wherein the parameter is the faradaic efficiency ηᵢ of the battery, calculated for said period by applying the following relation:
ηᵢ*Ah_{ch}=ηᵢ₋₁*Ah_{ch}+ΔCnom,
where Ah_{ch} represents the number of cumulated amperes-hours of the battery in charge phase during the period, ηᵢ₋₁ represents the faradaic efficiency of the previous period, and □Cnom corresponds to the interval between the value of the state variable at the end of a period and an estimated value.

3. The method of claim 1, wherein said first and second characteristics values are equal.

4. The method of claim 3, wherein said parameter is adapted so that the application, at the beginning of said period, of the adapted parameter value would have resulted, at the end of the period, in an identity during the comparison of said values of the state variable, the adapted parameter being used for a new period between two times characteristic of said state variable.

5. The method of any of claim 1, further comprising a storage of the estimated values of said variable, provided by the algorithm during said period, the stored values being used to adapt at least one parameter of the algorithm.

6. The method of any of claim 1, further comprising a storage of the variation, during said period, of one or a plurality of physical quantities influencing said variable, the values of the stored physical quantities being used to adapt at least one parameter of the algorithm.

7. The method of claim 6, wherein said quantity or quantities are selected from among the voltage across the battery, the charge or discharge current, the number of amperes-hours, the temperature, and the acoustic emissions of the battery.

8. The method of any of claim 1, wherein the state variable is the battery state of charge.

9. The method of any of claim 1, wherein the state variable is the battery state of aging.

10. A method of estimating a state variable of a battery comprising calibration phases according to the method of any of the foregoing claims.

11. A circuit for determining a state variable of a battery, capable of implementing the method of any of the foregoing claims.
